(19) United States
(12) Patent Application Publication
(10) Pub. No.: US 2025/0365924 A1
(43) Pub. Date: Nov. 27, 2025

(54) Memory Circuitry And Methods Used In Forming Memory Circuitry

(71) Applicant: Micron Technology, Inc., Boise, ID (US)

(72) Inventors: Yuichi Yokoyama, Boise, ID (US); Brenda Li, Boise, ID (US); Muralikrishnan Balakrishnan, Boise, ID (US)

(73) Assignee: Micron Technology, Inc., Boise, ID (US)

(21) Appl. No.: 19/179,504

(22) Filed: Apr. 15, 2025

Related U.S. Application Data
(60) Provisional application No. 63/650,319, filed on May 21, 2024.

(51) Int. Cl. H10B 12/00

(52) U.S. Cl. CPC H10B 12/30; H10B 12/03; H10B 12/05

(57) ABSTRACT

Memory circuitry comprises two memory-array regions individually comprising vertically-alternating tiers of insulative material and memory cells. Access lines extend horizontally to the memory cells in different ones of the memory-cell tiers. An intervening region is laterally between the two memory-array regions. The access lines extend into the intervening region along a first direction. The intervening region comprises vertically-alternating layers comprising first material and insulator material that are of different compositions relative one another. In the intervening region, there is an insulative wall extending through the access lines and the vertically-alternating layers and that is horizontally elongated in a second direction that is orthogonal to the first direction. The insulative wall has opposite first-direction sides and the layers of first material project horizontally there-into. Other embodiments, including method, are disclosed.

### TECHNICAL FIELD

Embodiments disclosed herein pertain to memory circuitry and to methods used in forming memory circuitry.

### BACKGROUND

Memory is one type of integrated circuitry and is used in computer systems for storing data. Memory may be fabricated in one or more arrays of individual memory cells. Memory cells may be written to, or read from, using digitlines (which may also be referred to as bitlines, data lines, or sense lines) and access lines (which may also be referred to as wordlines). The sense lines may conductively interconnect memory cells along columns of the array, and the access lines may conductively interconnect memory cells along rows of the array. Each memory cell may be uniquely addressed through the combination of a sense line and an access line.

Memory cells may be volatile, semi-volatile, or non-volatile. Non-volatile memory cells can store data for extended periods of time in the absence of power. Non-volatile memory is conventionally specified to be memory having a retention time of at least about 10 years. Volatile memory dissipates and is therefore refreshed/rewritten to maintain data storage. Volatile memory may have a retention time of milliseconds or less. Regardless, memory cells are configured to retain or store memory in at least two different selectable states. In a binary system, the states are considered as either a “0” or a “1”. In other systems, at least some individual memory cells may be configured to store more than two levels or states of information.

Memory cells may be arranged or arrayed in several manners including, for example, in a vertical stack (e.g., along a z direction) comprising a three-dimensional (3D) memory array region having horizontal tiers in which individual memory cells are received (e.g., arrayed in x and y directions). The stack in the 3D memory array region comprises vertically-alternating insulative tiers and conductive tiers (e.g., as part of memory-cell tiers) that extend into a stair-step region. The stair-step region includes individual “stairs” (alternately termed “steps” or “stair-steps”) that define contact regions of conductive lines of individual of the conductive tiers to which vertical conductive vias can contact to provide electrical access to/from those conductive lines.

### BRIEF DESCRIPTION OF THE DRAWINGS

FIG. 1 is a diagrammatic schematic of a DRAM memory array and peripheral circuitry in accordance with the prior art and in accordance with an embodiment of the invention.

FIG. 2 is an enlargement of a portion of FIG. 1.

FIG. 3 is a diagrammatic cross-sectional view of portions of a construction that will comprise circuitry in accordance with an embodiment of the invention.

FIGS. 4-35 are diagrammatic sequential sectional and/or enlarged views of the construction of FIG. 3, or portions thereof or alternate and/or additional embodiments, in process in accordance with some embodiments of the invention.

### DETAILED DESCRIPTION OF EXAMPLE EMBODIMENTS

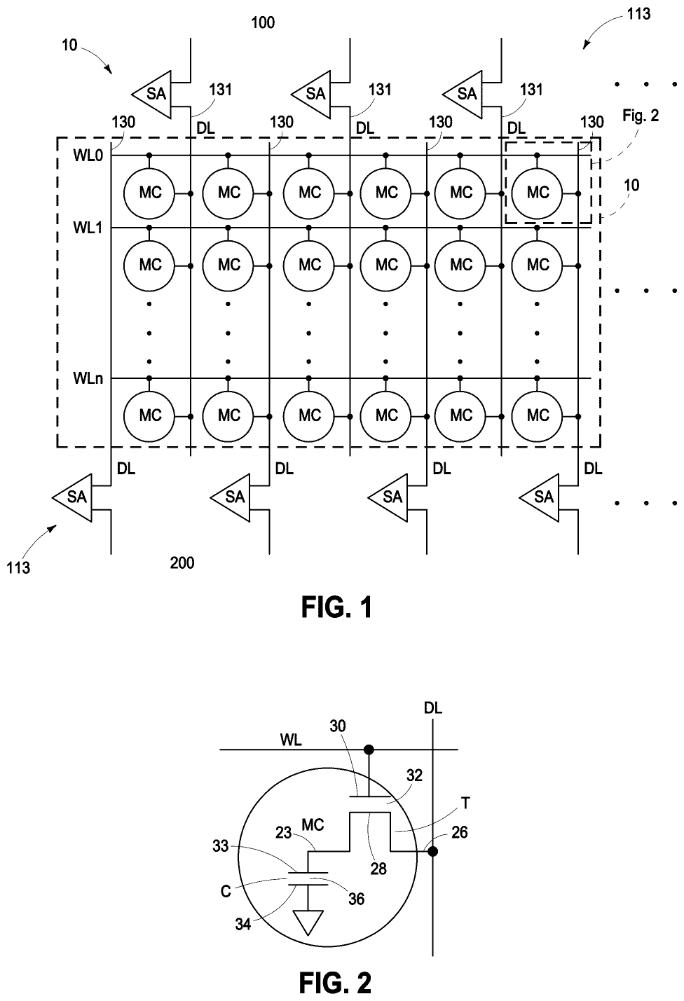

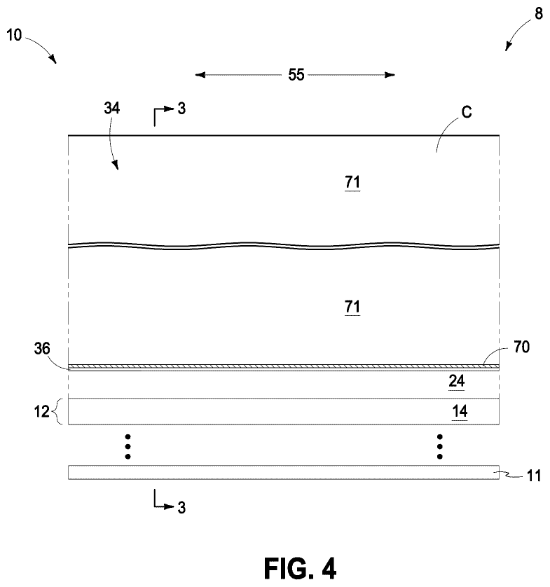

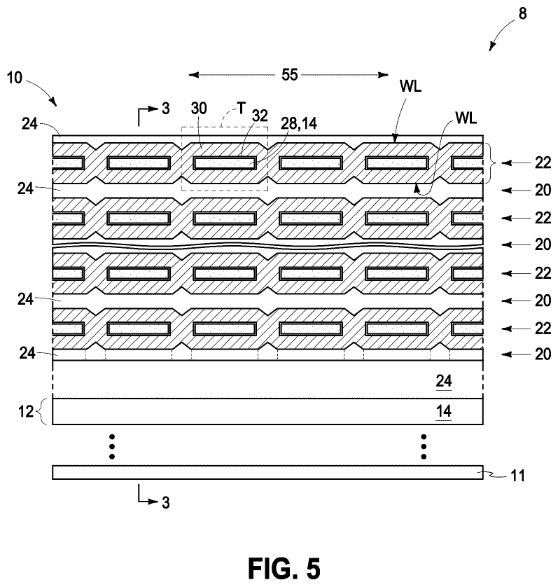

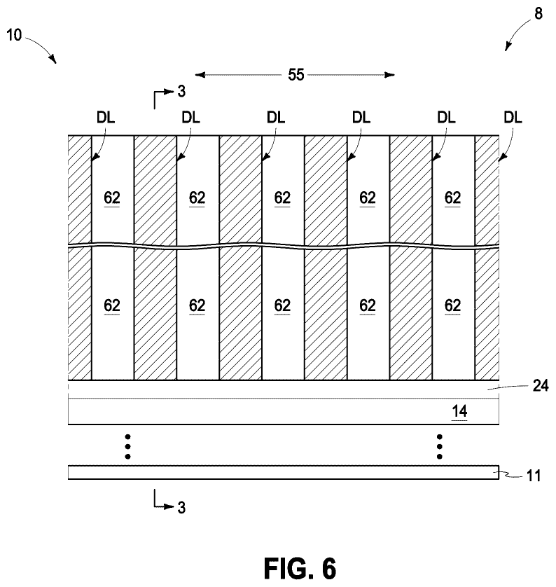

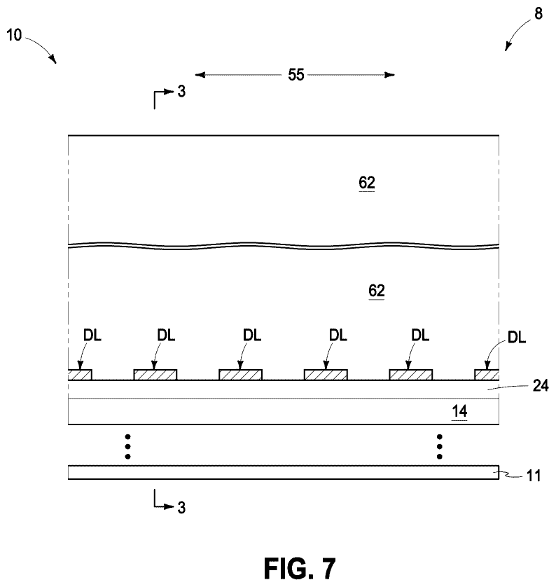

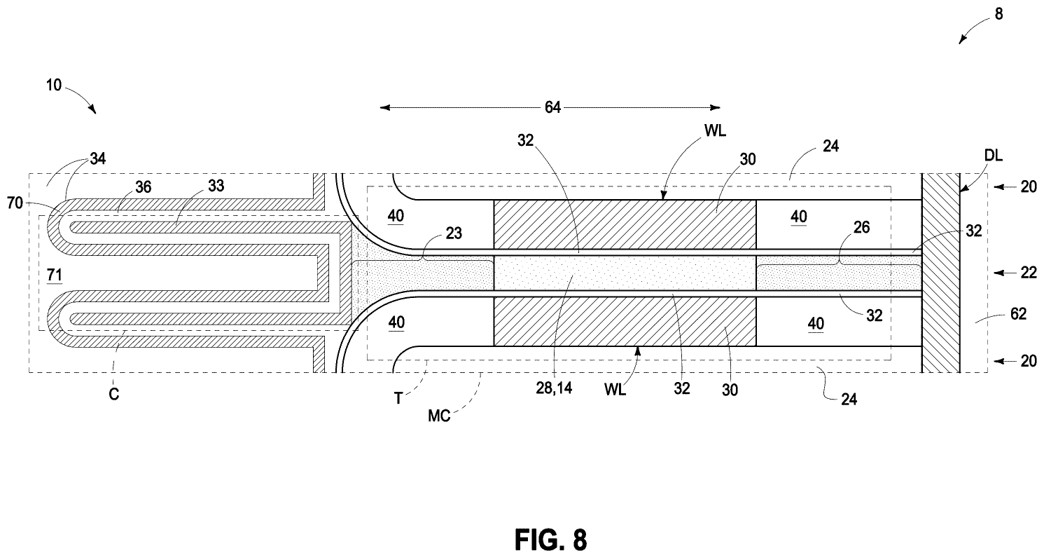

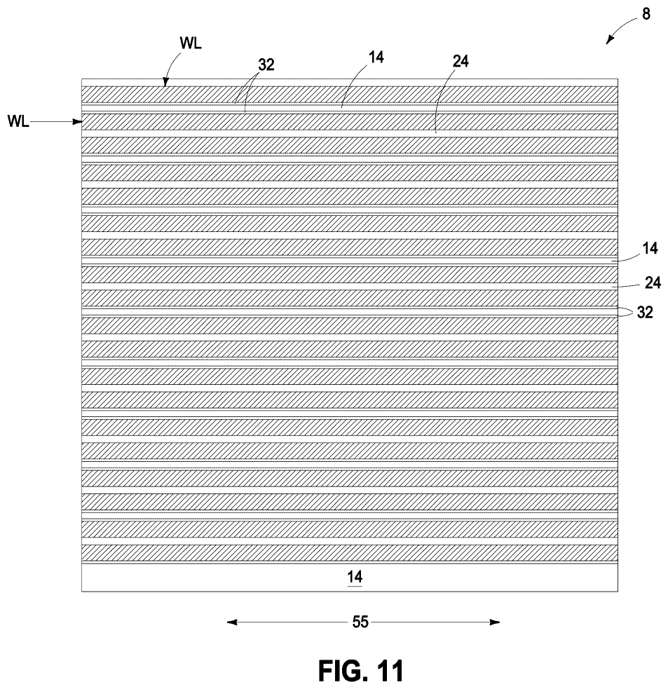

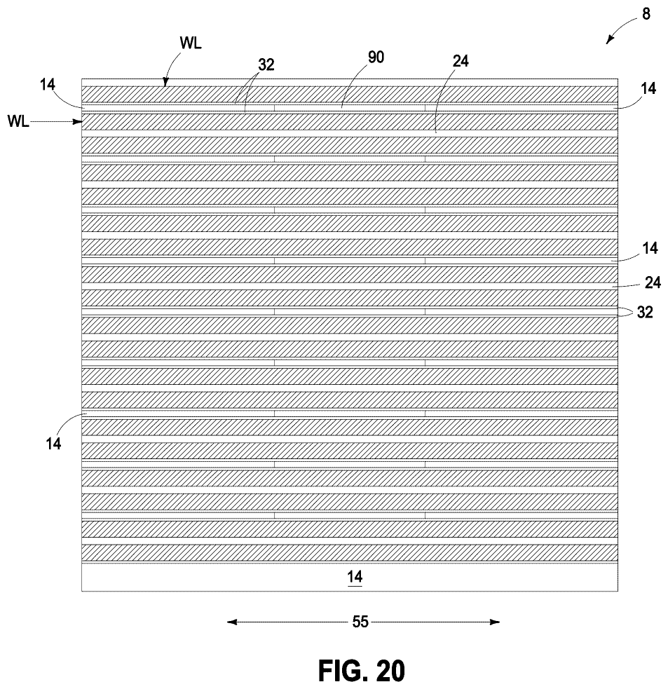

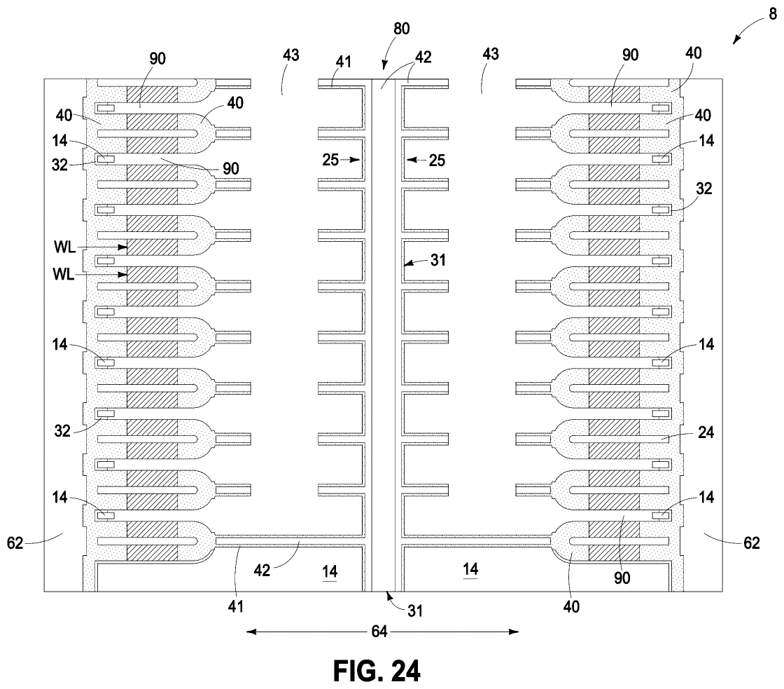

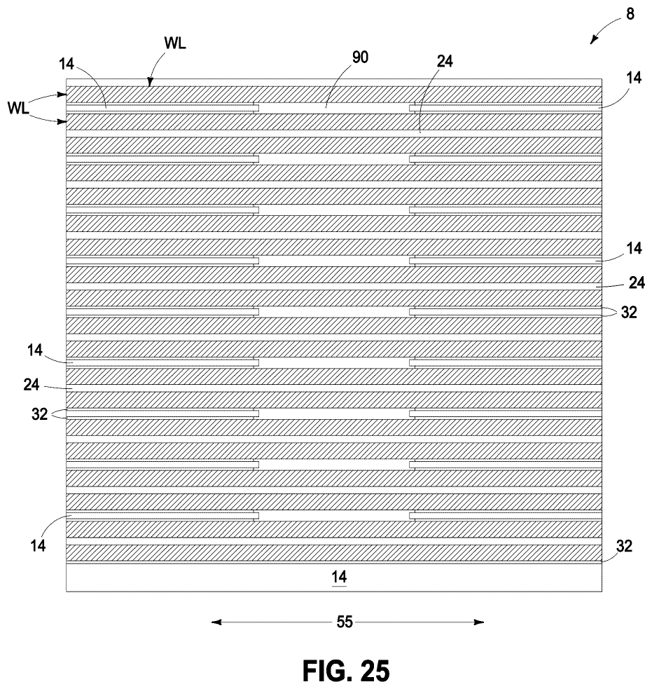

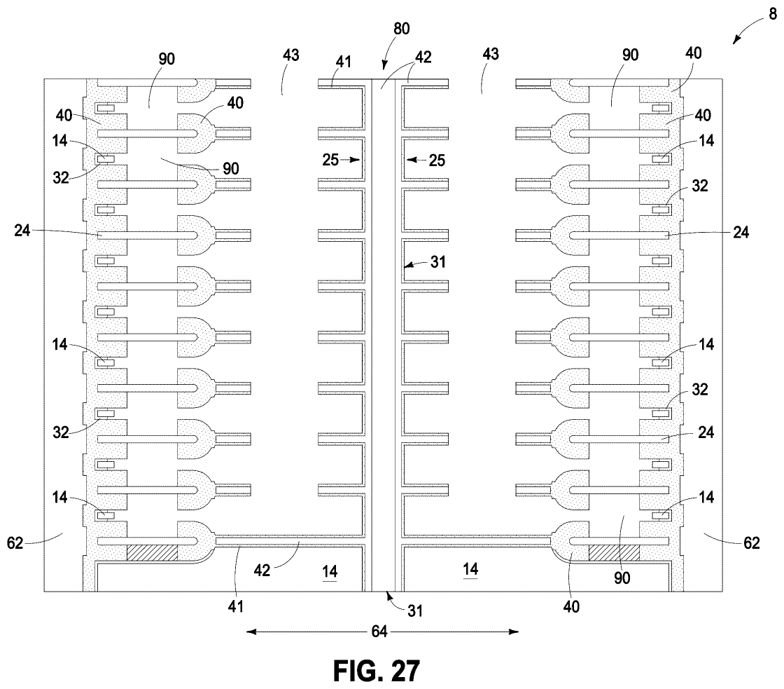

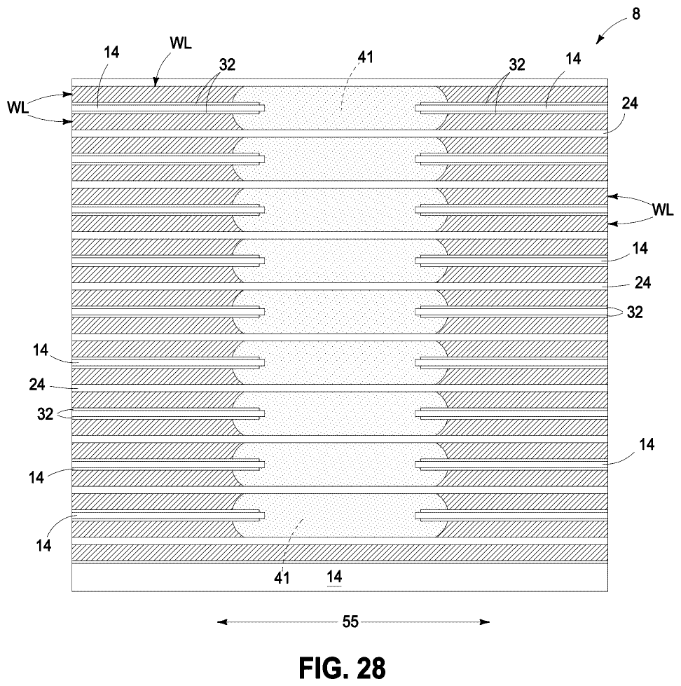

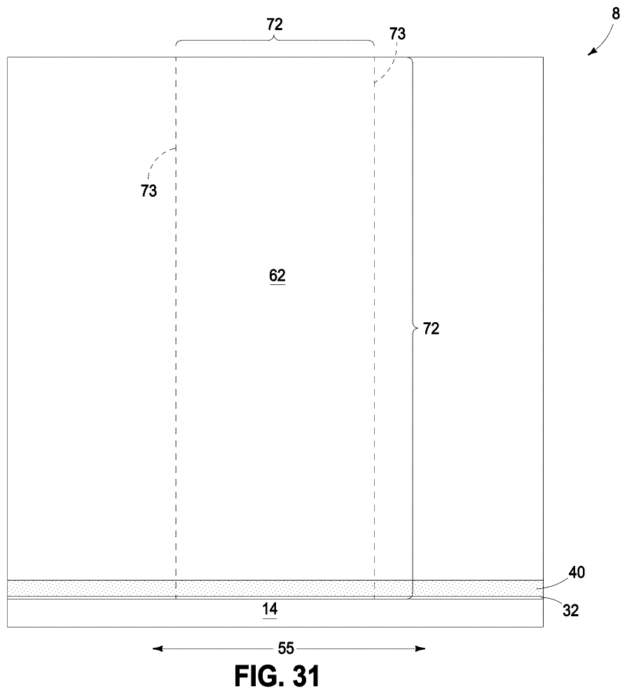

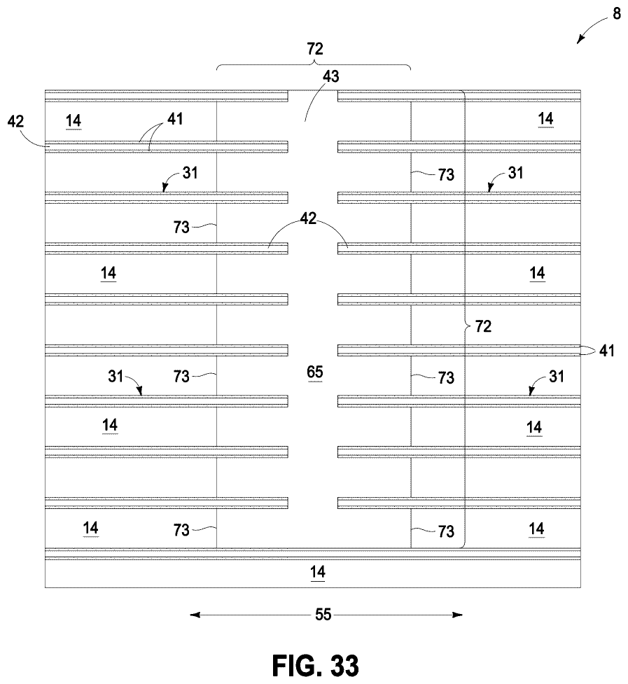

Embodiments of the invention encompass memory circuitry (e.g., DRAM) having vertically-alternating tiers of insulative material and memory cells, with the memory cells individually comprising a capacitor and a horizontally-oriented transistor. Embodiments of the invention also encompass methods used in forming such memory circuitry. Example method embodiments are first described with reference to FIGS. 1-35.

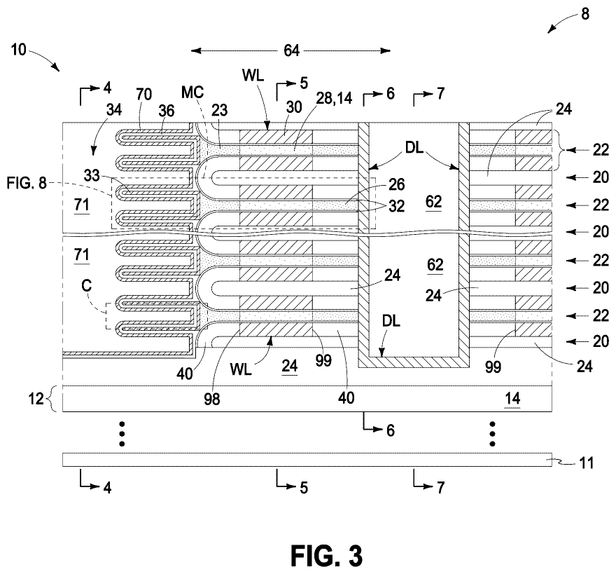

One example prior art schematic diagram of DRAM circuitry, and in accordance with an embodiment of the invention, is shown in FIGS. 1 and 2. FIG. 2 shows example memory cells MC individually comprising a transistor T and a capacitor C. One electrode of capacitor C is directly electrically coupled to a suitable potential (e.g., ground) and the other capacitor electrode is contacted with or comprises one of the source/drain regions of transistor T. The other source/drain region of transistor T is directly electrically coupled with a digitline/sense line 130 or 131 (also individually designated as DL). The gate of transistor T is directly electrically coupled with (e.g., comprises part of) a wordline/access line WL. FIG. 1 shows digitlines 130 and 131 extending from one of opposite sides 100 and 200 of a memory array area 10 into a peripheral circuitry area 113 that is aside memory array area 10. Digitlines 130 and 131 individually directly electrically couple with a sense amp SA on opposite sides 100 and 200 of array area 10 within peripheral circuitry area 113. Sense amps SA could be on only one side or all directly above or directly below memory array area 10. Non-schematic structure embodiments as shown herein in FIGS. 3+ have the wordlines/access lines running horizontally and the digitlines/sense lines running vertically.

Referring to FIGS. 3-11, an example fragment of a substrate construction 8 comprises two memory-array regions 10 and an intervening region 13 laterally there-between, both of such being above some base substrate 11. Substrate 11 may comprise any one or more of conductive/conductor/conducting, semiconductive/semiconductor/semiconducting, and insulative/insulator/insulating (i.e., electrically herein) materials. Materials may be aside, elevationally inward, or elevationally outward of the FIGS. 3-11-depicted materials. For example, other partially or wholly fabricated components of integrated circuitry may be provided somewhere above, about, or within base substrate 11. Control and/or other peripheral circuitry for operating components within a memory array may also be fabricated and may or may not be wholly or partially within a memory array or sub-array. Further, multiple sub-arrays may also be fabricated and operated independently, in tandem, or otherwise relative one another. As used in this document, a “sub-array” may also be considered as an array.

Semiconductor material 12 is above base substrate 11. In one embodiment, semiconductor material 12 comprises first material 14 (e.g., semiconductive material such as elemental monocrystalline or polycrystalline silicon and which may include one or more additional elements). If, by way of example, base substrate 11 is bulk monocrystalline silicon, first material 14 may be a part thereof such as an upper or uppermost portion of such bulk monocrystalline silicon.

Example memory circuitry (e.g., that of or comprising construction 8) comprises vertically-alternating insulative tiers 20 and memory-cell tiers 22 have been formed above semiconductor material 12. Example memory-cell tiers 22 comprise memory cells MC and example insulative tiers 20 comprise insulative material 24 (e.g., silicon dioxide). Memory cells MC individually comprise a horizontal transistor T comprising a gate 30 (e.g., conductive metal material) that is part of one of a plurality of horizontal conductive access lines WL that individually directly electrically couple together multiple of gates 30 of different ones of horizontal transistors T that are in the same memory-cell tier 22. Access lines WL extend horizontally along a first direction 55 and are laterally spaced from one another in a second direction 64 that is orthogonal to the first direction.

Example horizontal transistors T also comprise a first source/drain region 23, a second source/drain region 26, and a channel region 28 horizontally between the first and second source/drain regions. Regions 23, 26, and 28 of different immediately-horizontally-adjacent memory cells MC into and out of the plane of the page upon which FIG. 3 lies in a common memory-cell tier 22 may be isolated relative one another by insulative material (not shown). Gates 30 have a gate insulator 32 (e.g., dielectric or ferroelectric) between at least channel region 28 and gate 30 (e.g., gate-all-around the channel). An example insulator material 40 (e.g., silicon nitride) is laterally against lateral sides/edges of gates 30. Example memory cells MC also comprise a capacitor C having a first capacitor electrode 33 (e.g., a storage-node electrode), a second capacitor electrode 34 (e.g., comprising conductive metal material 70 and conductively-doped polysilicon 71), and a capacitor insulator 36 there-between (e.g., dielectric or ferroelectric). Second capacitor electrodes 34 of multiple capacitors C are directly electrically coupled with one another. First capacitor electrode 33 is directly coupled to first source/drain region 23 of transistor T. Digitlines DL extend through vertically-alternating tiers 20 and 22. Digitlines DL of different immediately-horizontally-adjacent memory cells MC into and out of the plane of the page upon which FIG. 3 lies in a common memory-cell tier 22 may be isolated relative one another by insulative material 62 (e.g., silicon dioxide and/or silicon nitride). Individual second source/drain regions 26 of individual transistors T that are in different memory-cell tiers 22 are directly electrically coupled to individual digitlines DL.

Example capacitors C and example horizontal transistors T are shown as already having been formed, although any of such could be formed later in processing not material to aspects of the inventions disclosed herein. Regardless, example manners not material to the inventions disclosed herein in forming that which is shown are, for example, shown in Micron Technology's U.S. Patent Application Publication Nos. 2022/0254784, 2022/0130834, U.S. Pat. No. 11,342,218, etc.

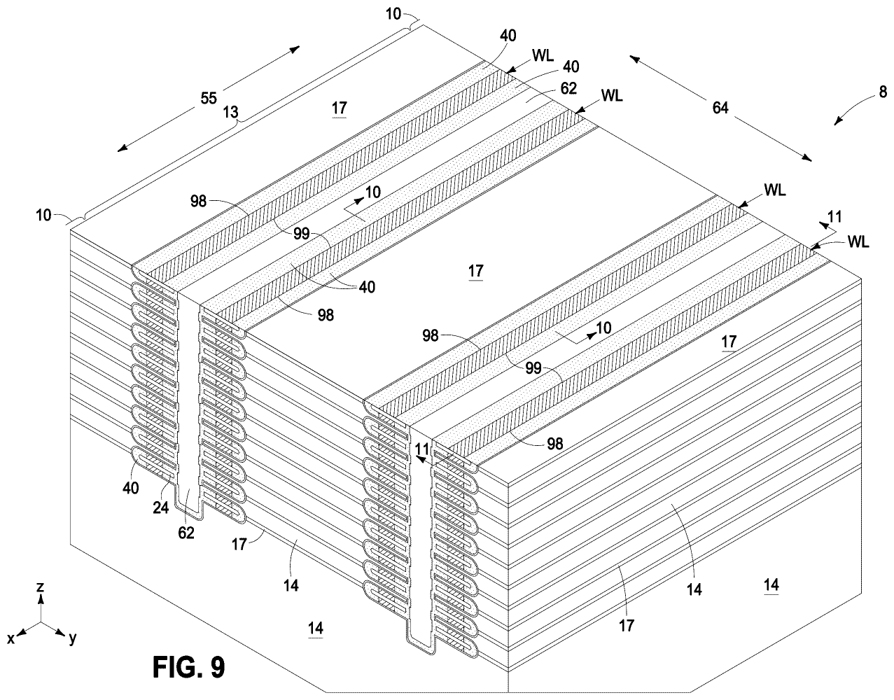

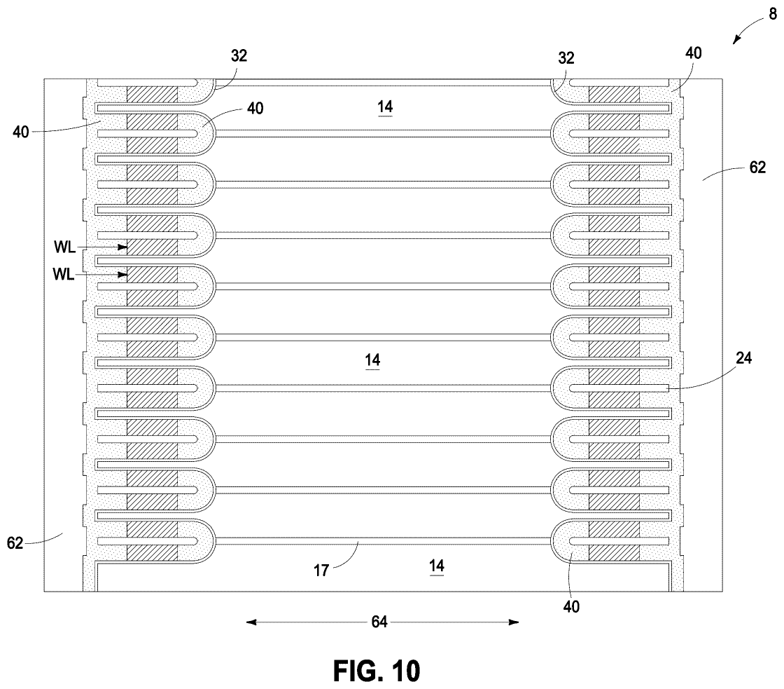

Access lines WL extend horizontally from memory-array regions 10 into intervening region 13 along first direction 55. By way of examples only, intervening region 13 may be between two memory array regions that are individually in different memory banks, for example at the edge of two immediately-55-direction-adjacent memory banks in a stair-case/stair-step region. Alternately, by way of example only, intervening region 13 may be in the middle of a memory bank wherein the two memory arrays are individually in the same memory bank (e.g., between two immediately-55-direction-adjacent stair-case/stair-step regions). Regardless, intervening region 13 comprises vertically-alternating layers comprising first material 14 and second material 17 that are of different compositions relative one another. An example second material 17 at least predominantly (more than 50% by volume up to and including 100% by volume) is silicon and germanium (e.g., an alloy of silicon and germanium). Regardless and as shown, first material 14 extends in second direction 64 to be vertically between immediately-vertically-adjacent access lines WL in intervening region 13. In one embodiment and as shown, two vertically-spaced gate-insulator layers 32 are vertically between immediately-vertically-adjacent access lines WL in intervening region 13. Example insulator material 40 in FIGS. 9 and 10 and subsequent figures is stippled, but not in earlier figures, for clarity.

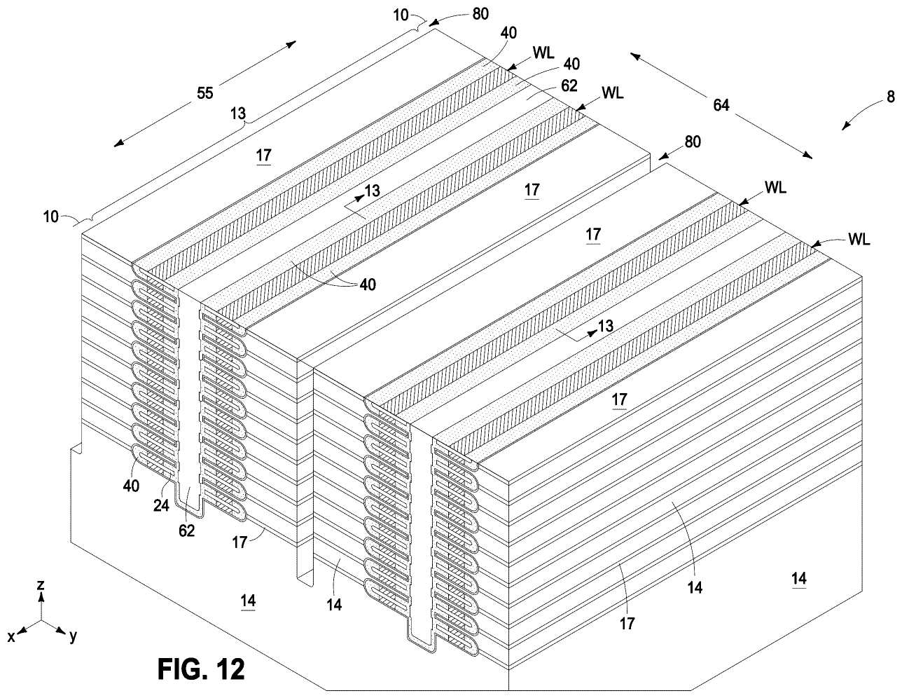

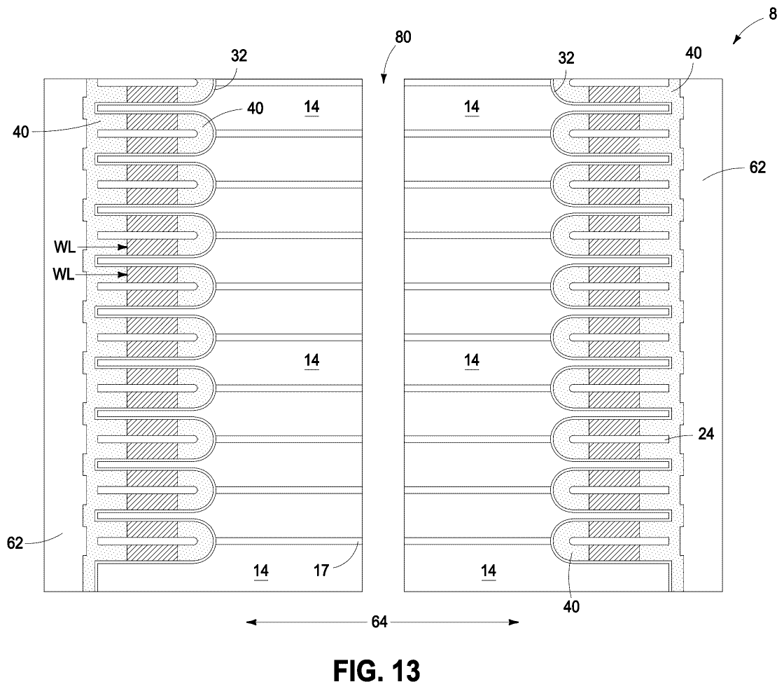

Referring to FIGS. 12 and 13, a trench 80 has been formed through the vertically-alternating layers in intervening region 13 and that is horizontally elongated along first direction 55.

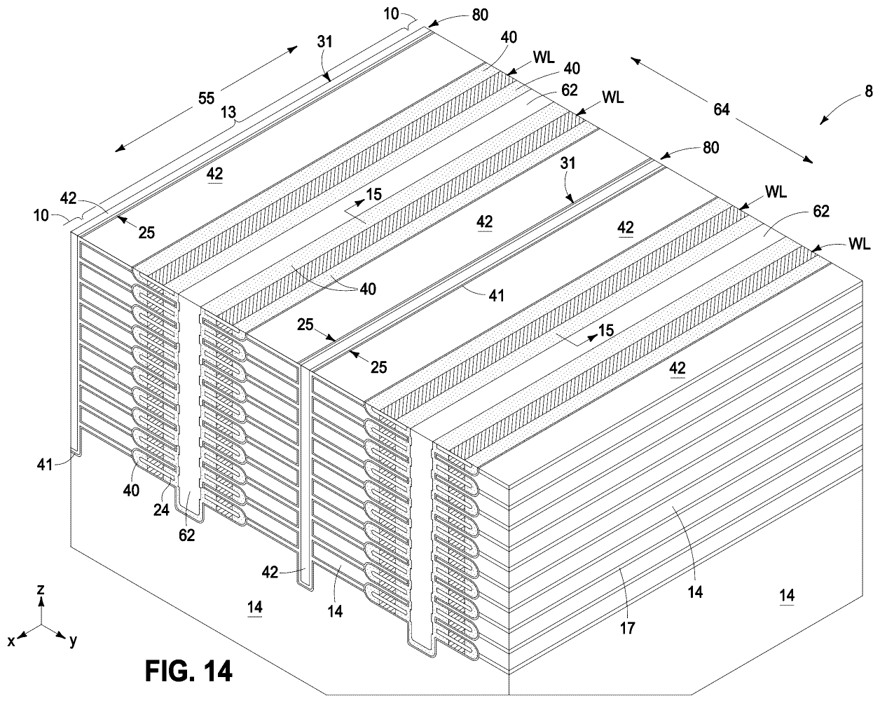

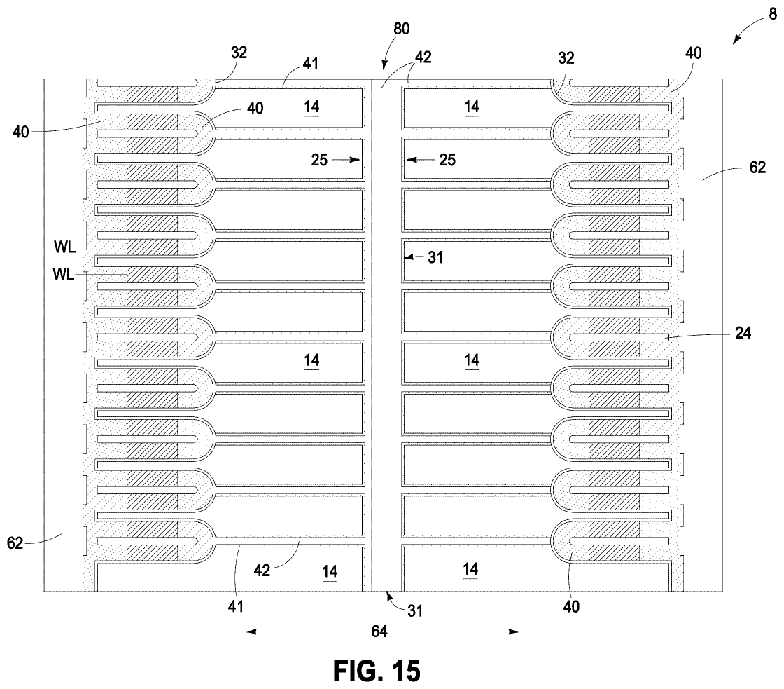

Referring to FIGS. 14 and 15, and through trench 80, second material 17 (no longer shown) has been replaced on opposite second-direction sides 25 of trench 80 with insulator material 31 and that is in trench 80. Such may occur, for example, by first etching second material 17 selectively relative to first material 14 (e.g., using a fluorine-containing gas if second material 17 is silicon-germanium and first material 14 is silicon). Some of first material 14 might be etched (as shown) while etching second material 17 and/or in a dedicated subsequent separate etch, or not at all (not shown). Regardless, insulator material 31 would be subsequently deposited, for example using a combination of atomic layer deposition (ALD) and as a spin-on-dielectric (SOD) that is subsequently solidified. In one embodiment, insulator material 31 comprises different-composition first and second insulative materials 41 and 42 (at least two), respectively. In one such embodiment, first insulative material 41 comprises silicon nitride and second insulative material 42 comprises silicon dioxide, with first insulative material 41 being formed before forming second insulative material 42. For example, first insulative material 41 could be deposited by ALD, followed by depositing initial second insulative material 42 by ALD, and followed by depositing more second insulative material 42 by an SOD method.

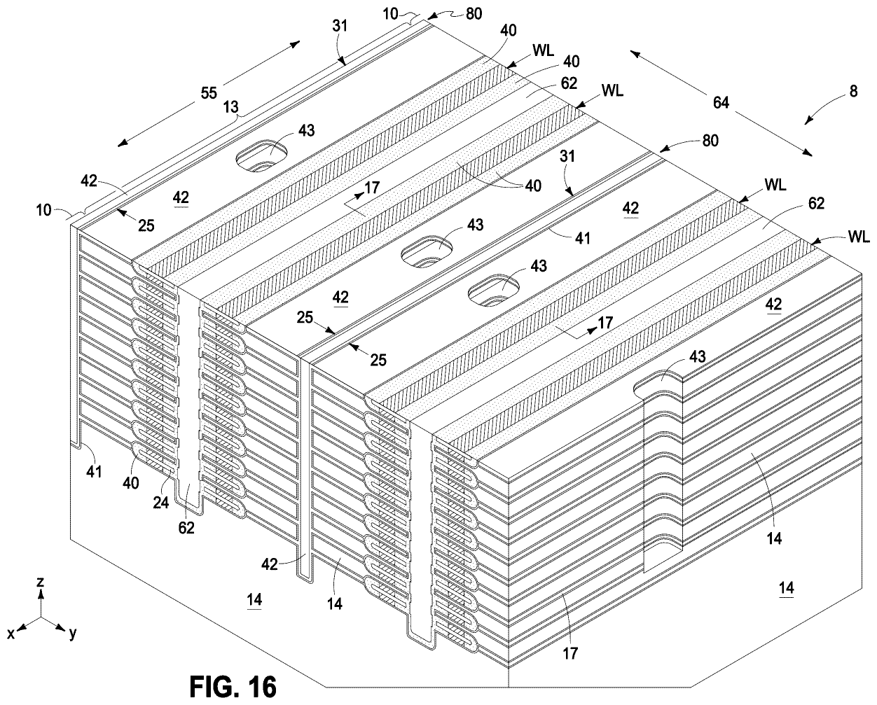

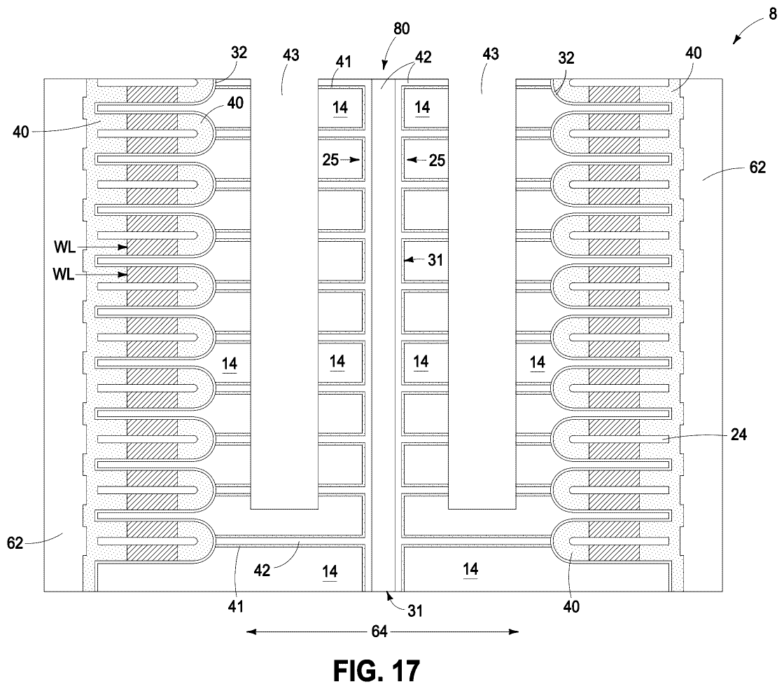

Referring to FIGS. 16 and 17, in intervening region 13, two openings 43 (at least two) have been formed through the first-material layers 14 and insulator material 31 and that are individually on opposite second-direction sides 25 of trench 80 (e.g., stopping somewhere in the lowest first-material layer 14). In one embodiment, trench 80 is formed deeper than openings 43 (e.g., into lower substrate material 14 as shown).

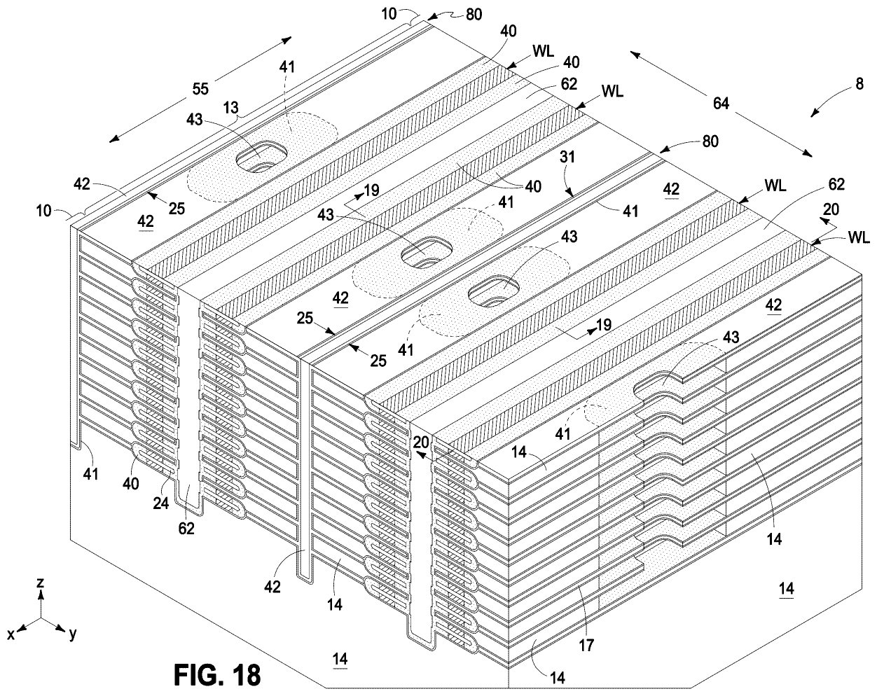

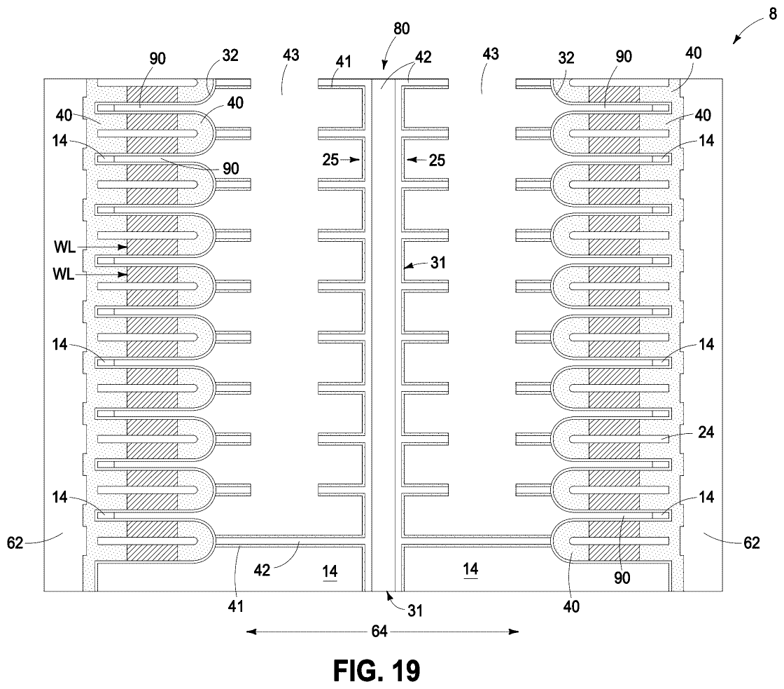

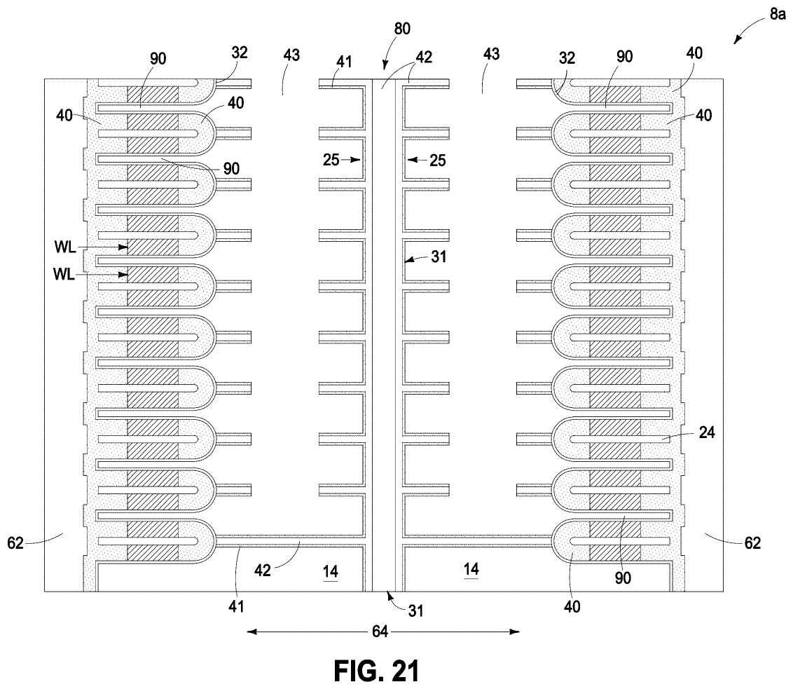

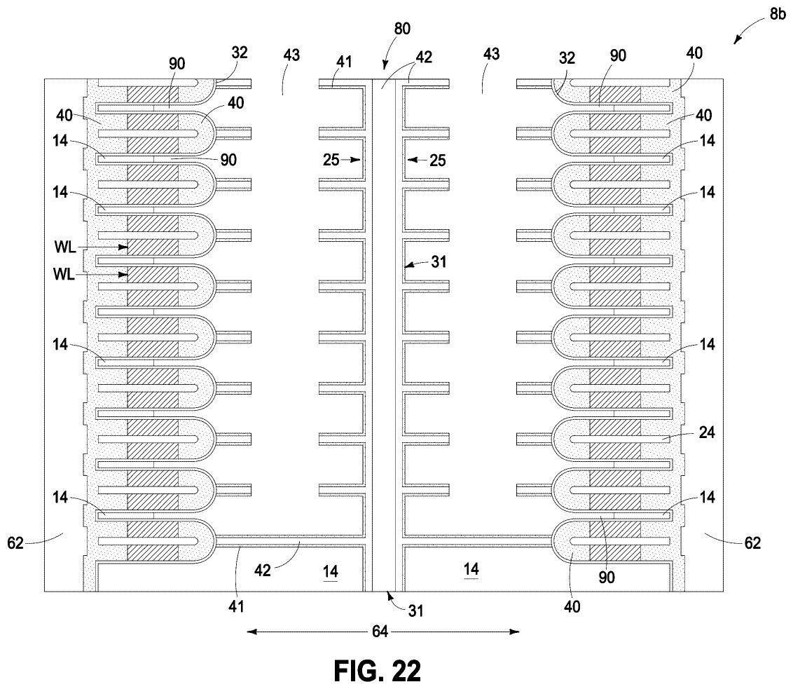

Referring to FIGS. 18-20, through openings 43, first material 14 has been removed (e.g., by etching) selectively relative to insulator material 31 (and perhaps gate insulator 32 when present) to remove at least some of first material 14 from being vertically between immediately-vertically-adjacent access lines WL in a vertical cross-section (e.g., that of FIG. 19) that is through openings 43 along (e.g., parallel to/with) second direction 64, thus leaving a gap 90 there-behind. Where first material 14 is silicon and materials 41 and 32 are silicon dioxide, example etching chemistries include HF, tetramethyl ammonium hydroxide, and a mixture of ammonia and hydrogen peroxide. In one embodiment and as shown, the removing of first material 14 removes all of first material 14 from being directly above and directly below immediately-vertically-adjacent access lines WL in the vertical cross-section. FIG. 19 shows some of first material 14 remaining in the vertical cross-section. FIG. 21 shows an alternate embodiment construction 8a where none of first material 14 remains in the vertical cross-section and FIG. 22 shows an alternate embodiment construction 8b where some of first material 14 remains directly above and directly below immediately-vertically-adjacent access lines WL in the vertical cross-section (i.e., only some of such having been removed).

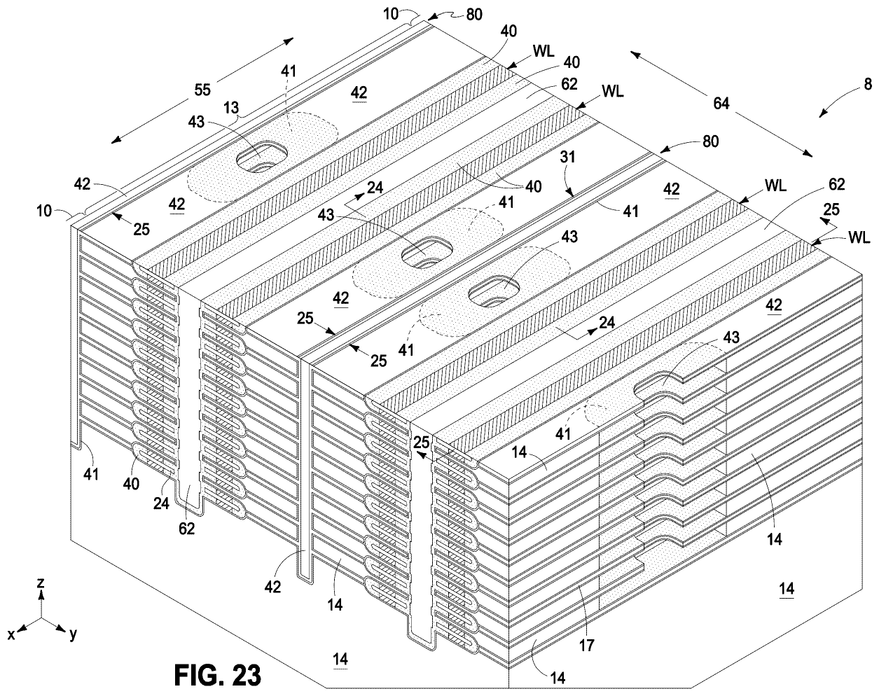

Referring to FIGS. 23-25, gate-insulator layers 32 (e.g., when present) have been removed through openings 43 from being between immediately-vertically-adjacent access lines WL (e.g., by etching selectively relative to material 14 [when present] and material 40 from within gaps 90; e.g., using HF is SiO_{X}).

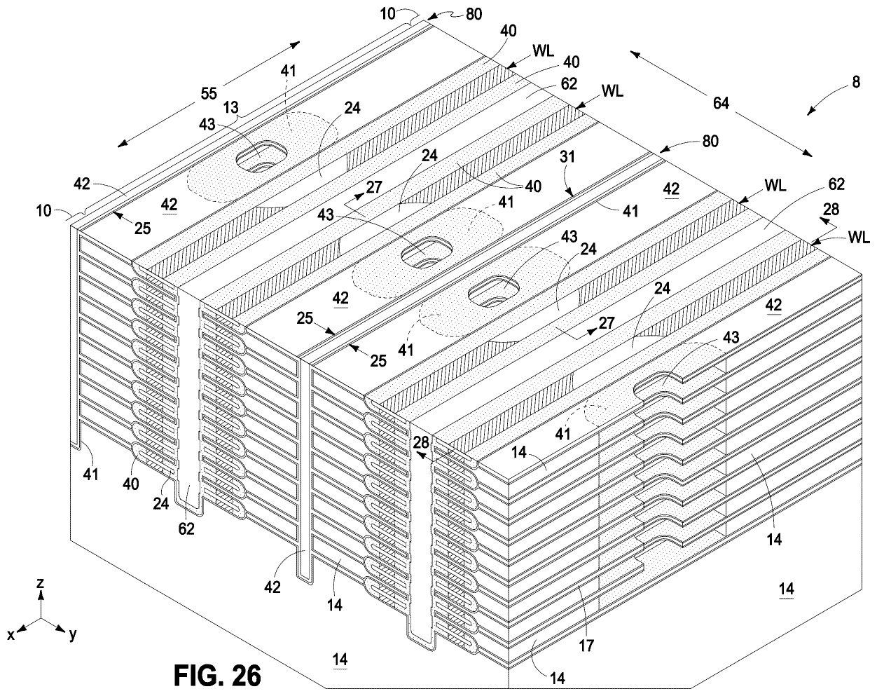

Referring to FIGS. 26-28, immediately-vertically-adjacent access lines WL in the vertical cross-section have been etched away through openings 43 (e.g., by etching selectively relative to materials 14 and 32 [when present] and materials 40 and 24 from within gaps 90; e.g., using a sulfuric acid hydrogen peroxide mix where the access lines are TiN).

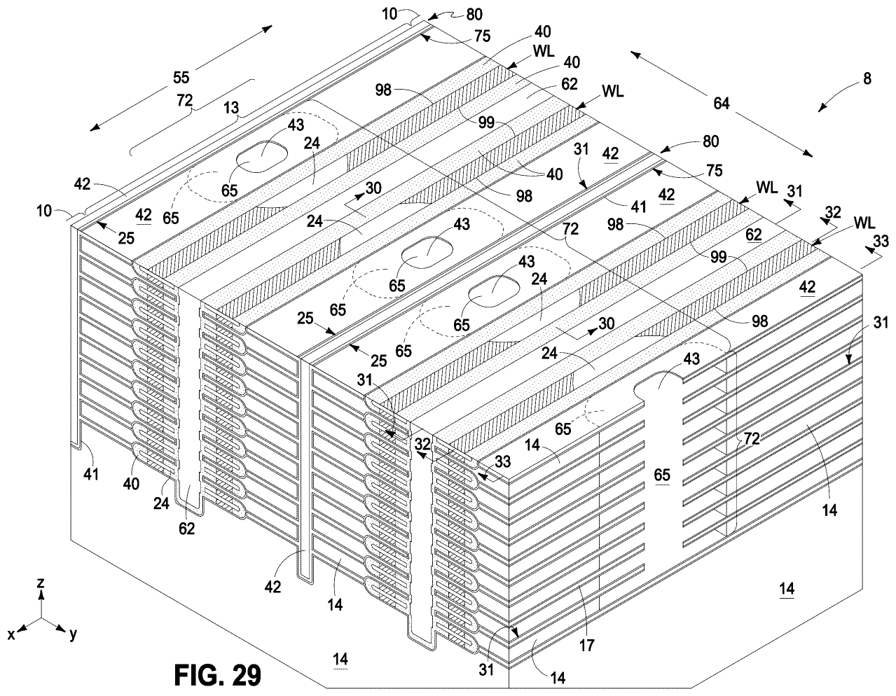

Referring to FIGS. 29-33, insulating material 65 (e.g., silicon dioxide and/or silicon nitride) has been formed in openings 43 (e.g., by a spin-on-dielectric process) to form an insulative wall 72 (in some embodiments referred to as a first wall 72) in intervening region 13 that is horizontally elongated in second direction 64. Insulative wall 72 extends vertically through access lines WL, first material 14, and insulator material 31.

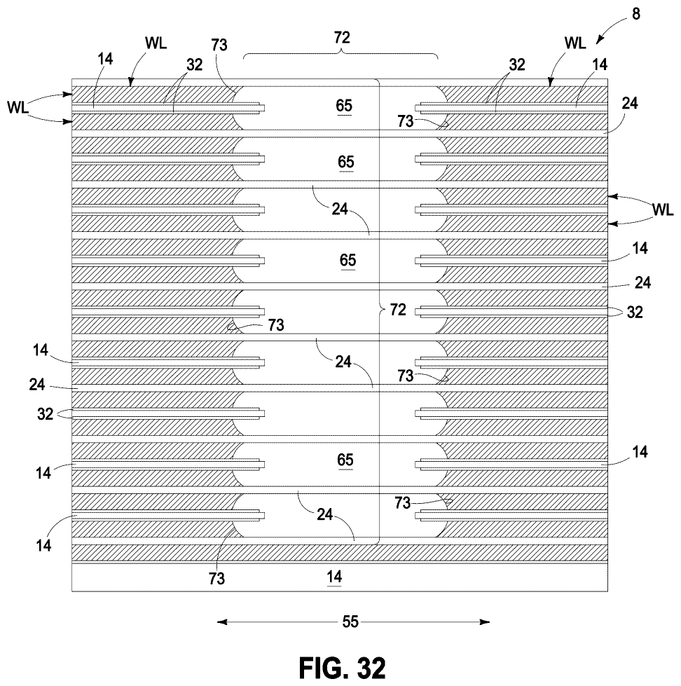

In one embodiment, insulative wall 72 has opposite first-direction sides 73, with layers of first material 14 projecting horizontally into insulative wall 72 from each of opposite first-direction sides 73 (FIG. 32). In one embodiment, insulator material 31 in trench 80 forms an insulator wall 75 (in some embodiments referred to as a second wall 75) in intervening region 13 and that is horizontally elongated in first direction 55 horizontally through insulative wall 72, with insulator wall 72 having first material 14 and insulator material 31 directly there-against on opposite second-direction sides 25.

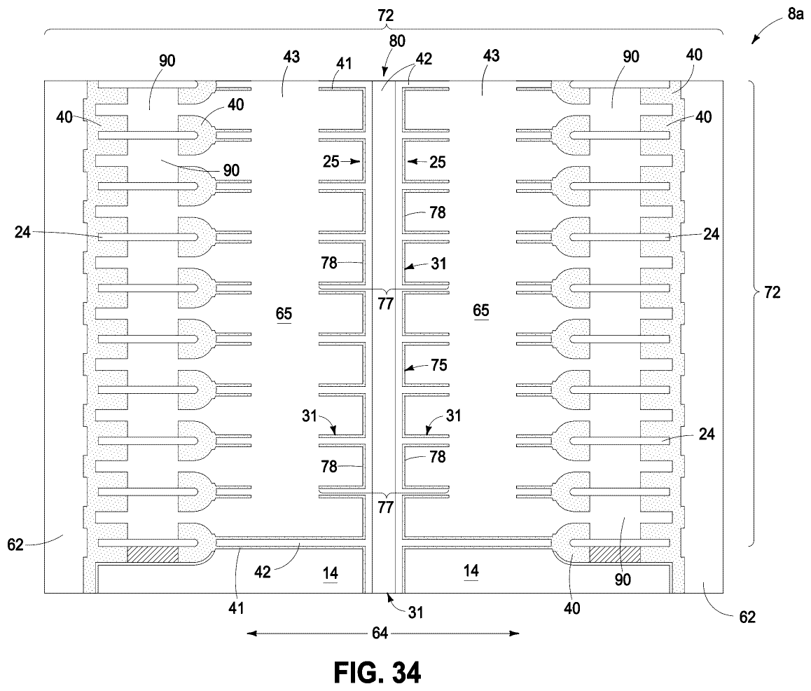

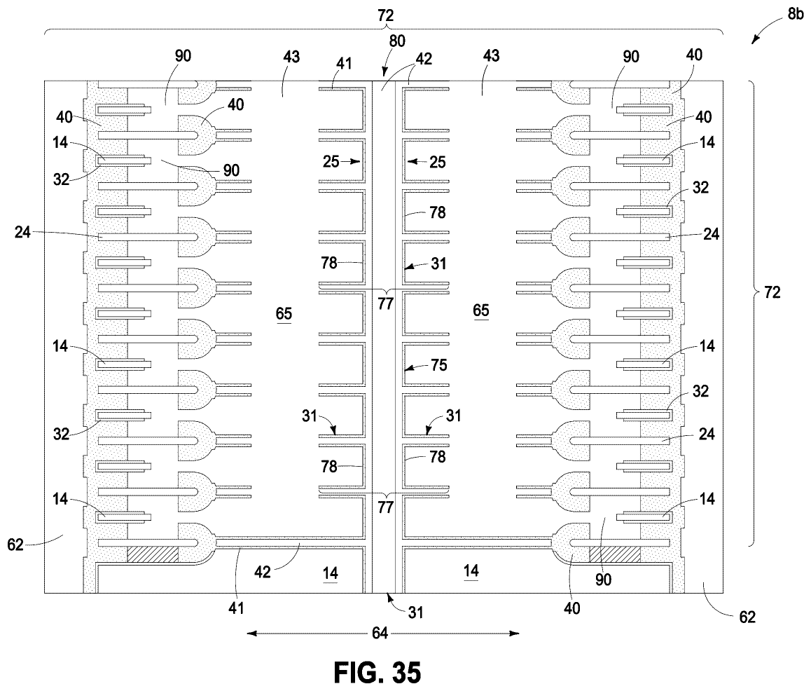

FIGS. 34 and 35 show alternate embodiment constructions 8a and 8b, respectively, that may result from processing described above with respect to FIGS. 23-33, yet from the constructions of FIGS. 21 and 22, respectively.

Method embodiments of the invention may enable and result in better access line/wordline WL separation horizontally and/or vertically (i.e., between those WL that are immediately-adjacent one another horizontally and/or vertically) than some prior methods.

Alternate embodiment constructions may result from method embodiments described above, or otherwise. Regardless, embodiments of the invention encompass circuitry independent of method of manufacture.

Nevertheless, such circuitry arrays may have any of the attributes as described herein in method embodiments. Likewise, the above-described method embodiments may incorporate, form, and/or have any of the attributes described with respect to device embodiments.

In one embodiment, memory circuitry (e.g., 8, 8a, 8b) comprises two memory-array regions (e.g., 10) individually comprising vertically-alternating tiers (e.g., 20, 22) of insulative material (e.g., 24) and memory cells (e.g., MC). Access lines (e.g., WL) extend horizontally to the memory cells in different ones of the memory-cell tiers. An intervening region (e.g., 13) is laterally between the two memory-array regions and the access lines extend into the intervening region along a first direction (e.g., 55). The intervening region comprises vertically-alternating layers comprising first material (e.g., 14) and insulator material (e.g., 31) that are of different compositions relative one another. In the intervening region, an insulative first wall (e.g., 72) extends through the access lines and the vertically-alternating layers and that is horizontally elongated in a second direction (e.g., 64) that is orthogonal to the first direction. In the intervening region, an insulative second wall (e.g., 75) extends through the vertically-alternating layers and is horizontally elongated in the first direction horizontally through the first wall. The second wall has the first material and the insulator material of the vertically-alternating layers directly there-against on opposite second-direction sides (e.g., 25) thereof.

In one embodiment, the second wall is taller than the first wall and in one embodiment the second wall extends horizontally through all of vertical thickness of the first wall.

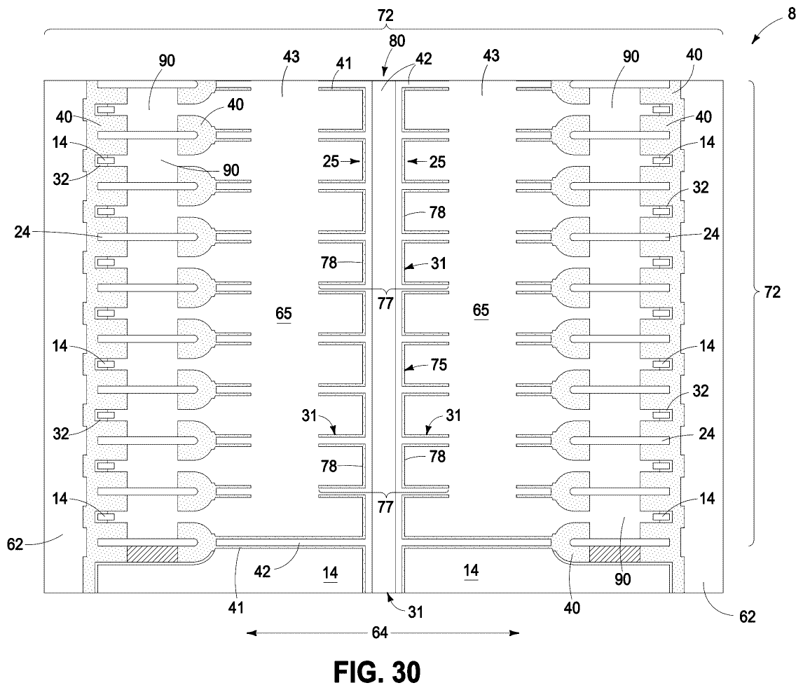

In one embodiment, the first wall comprises different composition first and second insulative materials (e.g., 41 and 42), with the second insulative material in a vertical cross-section along the second direction (e.g., that of any of FIGS. 30, 34, or 35) comprising a stack (e.g., indicated with bracket 72) of pairs (e.g., 77) of mirror-image C-like shapes (e.g., 78) that face away from one another.

In one embodiment, the memory cells individually comprise a horizontal transistor (e.g., T) and capacitor (e.g., C) electrically coupled (e.g., directly) therewith. The horizontal transistors individually comprise a gate (e.g., 30) that is part of one of the access lines that individually directly electrically couple together multiple of the gates of different ones of the horizontal transistors that are in the same one memory-cell tier (e.g., 22). Digitlines (e.g., DL) extend through the vertically-alternating tiers that individually directly electrically couple together multiple of the horizontal transistors in different ones of the memory-cell tiers. The access lines have a second-direction capacitor side (e.g., 98) and a second-direction digitline side (e.g., 99). The second-direction capacitor sides of immediately-laterally-adjacent of the access lines face towards one another. The second wall is laterally between the second-direction capacitor sides that face towards one another. In one such embodiment, the first wall comprises different composition first and second insulative materials (e.g., 41 and 42), with the second insulative material in a vertical cross-section along the second direction (e.g., that of FIG. 30) comprising a stack (e.g., indicated with bracket 72) of pairs (e.g., 77) of mirror-image C-like shapes (e.g., 78) that face away from one another. In one such latter embodiment, the first composition is horizontally between immediately-laterally-adjacent of the C-like shapes and in one embodiment the second wall is laterally centered in the second direction between the second-direction capacitor sides that face towards one another.

Any other attribute(s) or aspect(s) as shown and/or described herein with respect to other embodiments may be used.

In one embodiment, memory circuitry (e.g., 8, 8a, 8b) comprises two memory-array regions (e.g., 10) individually comprising vertically-alternating tiers (e.g., 20 and 22) of insulative material (e.g., 24) and memory cells (e.g., MC). Access lines (e.g., WL) extend horizontally to the memory cells in different ones of the memory-cell tiers. An intervening region (e.g., 13) is laterally between the two memory-array regions. The access lines extend into the intervening region along a first direction (e.g., 55). The intervening region comprises vertically-alternating layers comprising first material (e.g., 14) and insulator material (e.g., 31) that are of different compositions relative one another. In the intervening region, an insulative wall (e.g., 72) extends through the access lines and the vertically-alternating layers and that is horizontally elongated in a second direction (e.g., 64 that is orthogonal to the first direction). The insulative wall has opposite first-direction sides (e.g., 73), with the layers of first material projecting horizontally into the insulative wall from each of the opposite first-direction sides. In one such embodiment, the layers of first material project horizontally into the insulative wall from each of the opposite first-direction sides an equal distance from such opposite first-direction sides. Any other attribute(s) or aspect(s) as shown and/or described herein with respect to other embodiments may be used.

The above processing(s) or construction(s) may be considered as being relative to an array of components formed as or within a single stack or single deck of such components above or as part of an underlying base substrate (albeit, the single stack/deck may have multiple tiers). Control and/or other peripheral circuitry for operating or accessing such components within an array may also be formed anywhere as part of the finished construction, and in some embodiments may be under the array (e.g., CMOS under-array). Regardless, one or more additional such stack(s)/deck(s) may be provided or fabricated above and/or below that shown in the figures or described above. Further, the array(s) of components may be the same or different relative one another in different stacks/decks and different stacks/decks may be of the same thickness or of different thicknesses relative one another. Intervening structure may be provided between immediately-vertically-adjacent stacks/decks (e.g., additional circuitry and/or dielectric layers). Also, different stacks/decks may be electrically coupled relative one another. The multiple stacks/decks may be fabricated separately and sequentially (e.g., one atop another), or two or more stacks/decks may be fabricated at essentially the same time.

The assemblies and structures discussed above may be used in integrated circuits/circuitry and may be incorporated into electronic systems. Such electronic systems may be used in, for example, memory modules, device drivers, power modules, communication modems, processor modules, and application-specific modules, and may include multilayer, multichip modules. The electronic systems may be any of a broad range of systems, such as, for example, cameras, wireless devices, displays, chip sets, set top boxes, games, lighting, vehicles, clocks, televisions, cell phones, personal computers, automobiles, industrial control systems, aircraft, etc.

In this document unless otherwise indicated, “elevational”, “higher”, “upper”, “lower”, “top”, “atop”, “bottom”, “above”, “below”, “under”, “beneath”, “up”, and “down” are generally with reference to the vertical direction. “Horizontal” refers to a general direction (i.e., within 10 degrees) along a primary substrate surface and may be relative to which the substrate is processed during fabrication, and vertical is a direction generally orthogonal thereto. Reference to “exactly horizontal” is the direction along the primary substrate surface (i.e., no degrees there-from) and may be relative to which the substrate is processed during fabrication. Further, “vertical” and “horizontal” as used herein are generally perpendicular directions relative one another and independent of orientation of the substrate in three-dimensional space. Additionally, “elevationally-extending” and “extend(ing) elevationally” refer to a direction that is angled away by at least 450 from exactly horizontal. Further, “extend(ing) elevationally”, “elevationally-extending”, “extend(ing) horizontally”, “horizontally-extending” and the like with respect to a field effect transistor are with reference to orientation of the transistor's channel length along which current flows in operation between the source/drain regions. For bipolar junction transistors, “extend(ing) elevationally” “elevationally-extending”, “extend(ing) horizontally”, “horizontally-extending” and the like, are with reference to orientation of the base length along which current flows in operation between the emitter and collector. In some embodiments, any component, feature, and/or region that extends elevationally extends vertically or within 10° of vertical.

Further, “directly above”, “directly below”, and “directly under” require at least some lateral overlap (i.e., horizontally) of two stated regions/materials/components relative one another. Also, use of “above” not preceded by “directly” only requires that some portion of the stated region/material/component that is above the other be elevationally outward of the other (i.e., independent of whether there is any lateral overlap of the two stated regions/materials/components). Analogously, use of “below” and “under” not preceded by “directly” only requires that some portion of the stated region/material/component that is below/under the other be elevationally inward of the other (i.e., independent of whether there is any lateral overlap of the two stated regions/materials/components).

Any of the materials, regions, and structures described herein may be homogenous or non-homogenous, and regardless may be continuous or discontinuous over any material which such overlie. Where one or more example composition(s) is/are provided for any material, that material may comprise, consist essentially of, or consist of such one or more composition(s). Further, unless otherwise stated, each material may be formed using any suitable existing or future-developed technique, with atomic layer deposition, chemical vapor deposition, physical vapor deposition, epitaxial growth, diffusion doping, and ion implanting being examples.

Additionally, “thickness” by itself (no preceding directional adjective) is defined as the mean straight-line distance through a given material or region perpendicularly from a closest surface of an immediately-adjacent material of different composition or of an immediately-adjacent region. Additionally, the various materials or regions described herein may be of substantially constant thickness or of variable thicknesses. If of variable thickness, thickness refers to average thickness unless otherwise indicated, and such material or region will have some minimum thickness and some maximum thickness due to the thickness being variable. As used herein, “different composition” only requires those portions of two stated materials or regions that may be directly against one another to be chemically and/or physically different, for example if such materials or regions are not homogenous. If the two stated materials or regions are not directly against one another, “different composition” only requires that those portions of the two stated materials or regions that are closest to one another be chemically and/or physically different if such materials or regions are not homogenous. In this document, a material, region, or structure is “directly against” another when there is at least some physical touching contact of the stated materials, regions, or structures relative one another. In contrast, “over”, “on”, “adjacent”, “along”, and “against” not preceded by “directly” encompass “directly against” as well as construction where intervening material(s), region(s), or structure(s) result(s) in no physical touching contact of the stated materials, regions, or structures relative one another.

Herein, regions-materials-components are “electrically coupled” relative one another if in normal operation electric current is capable of continuously flowing from one to the other and does so predominately by movement of subatomic positive and/or negative charges when such are sufficiently generated. Another electronic component may be between and electrically coupled to the regions-materials-components. In contrast, when regions-materials-components are referred to as being “directly electrically coupled”, no intervening electronic component (e.g., no diode, transistor, resistor, transducer, switch, fuse, etc.) is between the directly electrically coupled regions-materials-components.

Any use of “row” and “column” in this document is for convenience in distinguishing one series or orientation of features from another series or orientation of features and along which components have been or may be formed. “Row” and “column” are used synonymously with respect to any series of regions, components, and/or features independent of function. Regardless, the rows may be straight and/or curved and/or parallel and/or not parallel relative one another, as may be the columns. Further, the rows and columns may intersect relative one another at 90° or at one or more other angles (i.e., other than the straight angle).

The composition of any of the conductive/conductor/conducting materials herein may be conductive metal material and/or conductively-doped semiconductive/semiconductor/semiconducting material. “Metal material” is any one or combination of an elemental metal, any mixture or alloy of two or more elemental metals, and any one or more metallic compound(s).

Herein, any use of “selective” as to etch, etching, removing, removal, depositing, forming, and/or formation is such an act of one stated material relative to another stated material(s) so acted upon at a rate of at least 2:1 by volume. Further, any use of selectively depositing, selectively growing, or selectively forming is depositing, growing, or forming one material relative to another stated material or materials at a rate of at least 2:1 by volume for at least the first 75 Angstroms of depositing, growing, or forming.

Unless otherwise indicated, use of “or” herein encompasses either and both.

### CONCLUSION

In some embodiments, a method used in forming memory circuitry comprises forming two memory-array regions and an intervening region laterally there-between. Access lines extend horizontally from the memory-array regions into the intervening region along a first direction. The intervening region comprises vertically-alternating layers comprising first material and second material that are of different compositions relative one another. The first material extends in a second direction that is orthogonal to the first direction to be vertically between immediately-vertically-adjacent of the access lines in the intervening region. In the intervening region, a trench is formed through the vertically-alternating layers and that is horizontally elongated along the first direction. Through the trench, the second material on opposite second-direction sides of the trench is replaced with insulator material and that is in the trench. In the intervening region, two openings are formed through the first-material layers and the insulator material and that are individually on the opposite second-direction sides of the trench. Through the openings, the first material is removed selectively relative to the insulator material to remove at least some of the first material from being vertically between the immediately-vertically-adjacent access lines in a vertical cross-section that is through the openings along the second direction. Through the openings, the immediately-vertically-adjacent access lines are etched away in the vertical cross-section. After the etching, insulating material is formed in the openings to form an insulative wall in the intervening region and that is horizontally elongated in the second direction. The insulative wall extends vertically through the access lines, the first material, and the insulator material.

In some embodiments, memory circuitry comprises two memory-array regions individually comprising vertically-alternating tiers of insulative material and memory cells. Access lines extend horizontally to the memory cells in different ones of the memory-cell tiers. An intervening region is laterally between the two memory-array regions. The access lines extend into the intervening region along a first direction. The intervening region comprises vertically-alternating layers comprising first material and insulator material that are of different compositions relative one another. In the intervening region, an insulative first wall extends through the access lines and the vertically-alternating layers and that is horizontally elongated in a second direction that is orthogonal to the first direction. In the intervening region, an insulative second wall extends through the vertically-alternating layers and that is horizontally elongated in the first direction horizontally through the first wall. The second wall has the first material and the insulator material of the vertically-alternating layers directly there-against on opposite second-direction sides thereof.

In some embodiments, memory circuitry comprises two memory-array regions individually comprising vertically-alternating tiers of insulative material and memory cells. Access lines extend horizontally to the memory cells in different ones of the memory-cell tiers. An intervening region is laterally between the two memory-array regions. The access lines extend into the intervening region along a first direction. The intervening region comprises vertically-alternating layers comprising first material and insulator material that are of different compositions relative one another. In the intervening region, an insulative wall extends through the access lines and the vertically-alternating layers and that is horizontally elongated in a second direction that is orthogonal to the first direction. The insulative wall has opposite first-direction sides. The layers of first material project horizontally into the insulative wall from each of the opposite first-direction sides.

In compliance with the statute, the subject matter disclosed herein has been described in language more or less specific as to structural and methodical features. It is to be understood, however, that the claims are not limited to the specific features shown and described, since the means herein disclosed comprise example embodiments. The claims are thus to be afforded full scope as literally worded, and to be appropriately interpreted in accordance with the doctrine of equivalents.

1. A method used in forming memory circuitry, comprising:
forming two memory-array regions and an intervening region laterally there-between, access lines extending horizontally from the memory-array regions into the intervening region along a first direction, the intervening region comprising vertically-alternating layers comprising first material and second material that are of different compositions relative one another, the first material extending in a second direction that is orthogonal to the first direction to be vertically between immediately-vertically-adjacent of the access lines in the intervening region;
in the intervening region, forming a trench through the vertically-alternating layers and that is horizontally elongated along the first direction;
through the trench, replacing the second material on opposite second-direction sides of the trench with insulator material and that is in the trench;
in the intervening region, forming two openings through the first-material layers and the insulator material and that are individually on the opposite second-direction sides of the trench;
through the openings, removing the first material selectively relative to the insulator material to remove at least some of the first material from being vertically between the immediately-vertically-adjacent access lines in a vertical cross-section that is through the openings along the second direction;
through the openings, etching away the immediately-vertically-adjacent access lines in the vertical cross-section; and
after the etching, forming insulating material in the openings to form an insulative wall in the intervening region and that is horizontally elongated in the second direction; the insulative wall extending vertically through the access lines, the first material, and the insulator material.

2. The method of claim 1 wherein the first material is semiconductive.

3. The method of claim 2 wherein the first material at least predominantly comprises silicon and the second material at least predominantly comprises silicon and germanium.

4. The method of claim 1 wherein the trench is formed deeper than the openings.

5. The method of claim 1 wherein the insulator material comprises different composition first and second insulative materials.

6. The method of claim 5 wherein the first insulative material comprises silicon nitride and the second insulative material comprises silicon dioxide, the first insulative material being formed before forming the second insulative material.

7. The method of claim 1 wherein two vertically-spaced gate-insulator layers are vertically between the immediately-vertically-adjacent access lines in the intervening region and further comprising:
before the etching, removing the gate-insulator layers through the openings.

8. The method of claim 1 wherein the removing of the first material removes all of the first material from being directly above and directly below the immediately-vertically-adjacent access lines in the vertical cross-section.

9. The method of claim 8 wherein the removing of the first material removes all of the first material from being in the vertical cross-section in the intervening region.

10. The method of claim 1 wherein the removing of the first material removes only some of the first material from being directly above and directly below the immediately-vertically-adjacent access lines in the vertical cross-section.

11. The method of claim 1 wherein the insulative wall has opposite first-direction sides, the layers of first material projecting horizontally into the insulative wall from each of the opposite first-direction sides.

12. The method of claim 1 wherein the insulating material in the trench forms an insulator wall in the intervening region that is horizontally elongated in the first direction horizontally through the insulative wall, the insulator wall having the first material and the insulator material directly there-against on the opposite second-direction sides.

13. The method of claim 12 wherein the insulative wall has opposite first-direction sides, the layers of first material projecting horizontally into the insulative wall from each of the opposite first-direction sides.

14. Memory circuitry comprising:
two memory-array regions individually comprising vertically-alternating tiers of insulative material and memory cells, access lines extending horizontally to the memory cells in different ones of the memory-cell tiers;
an intervening region laterally between the two memory-array regions, the access lines extending into the intervening region along a first direction, the intervening region comprising vertically-alternating layers comprising first material and insulator material that are of different compositions relative one another;
in the intervening region, an insulative first wall extending through the access lines and the vertically-alternating layers and that is horizontally elongated in a second direction that is orthogonal to the first direction; and
in the intervening region, an insulative second wall extending through the vertically-alternating layers and that is horizontally elongated in the first direction horizontally through the first wall; the second wall having the first material and the insulator material of the vertically-alternating layers directly there-against on opposite second-direction sides thereof.

15. The memory circuitry of claim 14 wherein the second wall is taller than the first wall.

16. The memory circuitry of claim 14 wherein the second wall extends horizontally through all of vertical thickness of the first wall.

17. The memory circuitry of claim 16 wherein the second wall is taller than the first vertical wall.

18. The memory circuitry of claim 14 wherein the first wall comprises different composition first and second insulative materials, the second insulative material in a vertical cross-section along the second direction comprising a stack of pairs of mirror-image C-like shapes that face away from one another.

19. The memory circuitry of claim 18 wherein the first composition is horizontally between immediately-laterally-adjacent of the C-like shapes.

20. Memory circuitry comprising:
two memory-array regions individually comprising vertically-alternating tiers of insulative material and memory cells, access lines extending horizontally to the memory cells in different ones of the memory-cell tiers;
an intervening region laterally between the two memory-array regions, the access lines extending into the intervening region along a first direction, the intervening region comprising vertically-alternating layers comprising first material and insulator material that are of different compositions relative one another; and
in the intervening region, an insulative wall extending through the access lines and the vertically-alternating layers and that is horizontally elongated in a second direction that is orthogonal to the first direction, the insulative wall having opposite first-direction sides, the layers of first material projecting horizontally into the insulative wall from each of the opposite first-direction sides.
